(19) United States
(12) Patent Application Publication
(10) Pub. No.: US 2026/0327480 A1
(43) Pub. Date: Oct. 22, 2026

(54) QUANTUM DOT SOLUTION AND LIGHT-EMITTING ELEMENT

(71) Applicant: Sharp Display Technology Corporation, Kameyama City, Mie (JP)

(72) Inventors: Yukio TAKENAKA, Sakai City, Osaka (JP); Yuma YAGUCHI, Sakai City, Osaka (JP)

(21) Appl. No.: 19/117,442

(22) PCT Filed: Oct. 14, 2022
(86) PCT No.: PCT/JP2022/038460

§ 371 Date: Apr. 1, 2025

(51) Int. Cl. C09K 11/02; C09K 11/56; C09K 113/00; H10K 50/115; H10K 85/30

(52) U.S. Cl. CPC C09K 11/025; C09K 11/565; H10K 85/381; C09K 2113/00; H10K 50/115

(57) ABSTRACT

A quantum dot solution includes a light-emitting quantum dot, a precursor of a metal sulfide, and a solvent, in which the precursor is a metal complex having a weight loss rate of 60% to 90% when heated from 50 °C to 200 °C, a solid obtained after the metal complex is heated to 200 °C includes 80 wt % or more of an inorganic compound, and 50 wt % or more of the inorganic compound is the metal sulfide.

### TECHNICAL FIELD

The disclosure relates to a quantum dot solution and the like.

### BACKGROUND ART

PTL 1 discloses a method for manufacturing a quantum dot-containing coating film using a composition including quantum dots containing a chalcogenide as a surface material, a base material component, and a solvent.

### CITATION LIST

### Patent Literature

PTL 1: JP 2020-101769 A

### SUMMARY

### Technical Problem

A quantum dot layer modified with an organic ligand has a problem of low durability. In addition, a quantum dot layer coated with an inorganic material formed by a known method has a problem of a low carrier injection property.

### Solution to Problem

A quantum dot solution according to an aspect of the disclosure is a quantum dot solution including a light-emitting quantum dot, a precursor of a metal sulfide, and a solvent, in which the precursor is a metal complex having a weight loss rate of 60% to 90% when heated from 50 °C to 200 °C, a solid obtained after the metal complex is heated to 200 °C includes 80 wt % or more of an inorganic compound, and 50 wt % or more of the inorganic compound is the metal sulfide.

### Advantageous Effects of Disclosure

By using the quantum dot solution according to an aspect of the disclosure, it is possible to increase durability while maintaining carrier injection properties of the quantum dot layer.

### BRIEF DESCRIPTION OF DRAWINGS

FIG. 1 is a flowchart depicting a method for forming a quantum dot layer according to an embodiment.

FIG. 2 is a schematic view illustrating a method for forming a quantum dot layer according to the embodiment.

FIG. 3 is an example of structural formulae of ligands and metal complexes.

FIG. 4 is a graph depicting thermogravimetric characteristics of metal complexes. FIG. 5 includes graphs depicting the X-ray diffraction profiles of zinc xanthate before and after heating and the X-ray diffraction profile of zinc sulfide.

FIG. 6A is a graph depicting the results of Fourier transform infrared spectroscopy (FTIR) measurement after heating zinc xanthate.

FIG. 6B is a graph depicting the results of Fourier transform infrared spectroscopy (FTIR) measurement after heating zinc xanthate.

FIG. 6C is a graph depicting the results of Fourier transform infrared spectroscopy (FTIR) measurement after heating zinc xanthate.

FIG. 6D is a graph depicting the results of Fourier transform infrared spectroscopy (FTIR) measurement after heating zinc xanthate.

FIG. 6E is a graph depicting the results of Fourier transform infrared spectroscopy (FTIR) measurement after heating zinc xanthate.

FIG. 7A is a graph depicting a part of FIG. 6E in an enlarged manner.

FIG. 7B is a graph depicting the results of Fourier transform infrared spectroscopy (FTIR) measurements of an organic ligand.

FIG. 8A is an ultraviolet-visible absorption spectrum (UV-VIS) of a thin film obtained by heating an application liquid of zinc xanthate.

FIG. 8B is a Tauc plot graph of a thin film obtained by heating an application liquid of zinc xanthate.

FIG. 9 is a schematic view illustrating another formation method of a quantum dot layer.

FIG. 10 is a table showing the results obtained by comparing a quantum dot layer of a comparative example and a quantum dot layer of the embodiment in terms of structure, PLQY (photoluminescence quantum efficiency), and PL lifetime (photoluminescence lifetime).

FIG. 11A is a graph depicting the results of a light exposure test in the atmosphere of a quantum dot layer of the comparative example and results of a light exposure test in the atmosphere of a quantum dot layer of the embodiment.

FIG. 11B is a graph depicting the results of a heating test in nitrogen of a quantum dot layer of the comparative example and the results of a heating test in nitrogen of a quantum dot layer of the embodiment.

FIG. 12 is a schematic view illustrating an example of a preparation method of a quantum dot solution.

FIG. 13 is a graph depicting the relationship between the molar ratio of potassium xanthate to zinc chloride (chloro ion source) in a solution used for preparation of a quantum dot solution and PLQY.

FIG. 14 includes schematic views illustrating a modified state of quantum dots.

FIG. 15 is a schematic cross-sectional view illustrating a configuration example of a light-emitting element of the present embodiment.

FIG. 16 is a cross-sectional photograph illustrating a configuration example of a light-emitting element of the present embodiment.

FIG. 17 is a graph depicting current density-external quantum effect characteristics of a light-emitting element.

FIG. 18 is a graph depicting voltage-current density characteristics of a light-emitting element.

FIG. 19 is a graph depicting EL spectra at a current density of 10 mA/m² in the embodiment and the comparative example.

FIG. 20A is a graph depicting temporal changes in relative luminance and voltage when a constant current of 25 mA/m² is continuously supplied to a light-emitting element of the embodiment.

FIG. 20B is a graph depicting temporal changes in relative luminance and voltage when a constant current of 25 mA/m² is continuously supplied to a light-emitting element of the comparative example.

FIG. 21 is a schematic diagram illustrating a configuration example of a display device according to the embodiment.

FIG. 22 is a cross-sectional view illustrating a configuration example of a display device according to the embodiment.

### DESCRIPTION OF EMBODIMENTS

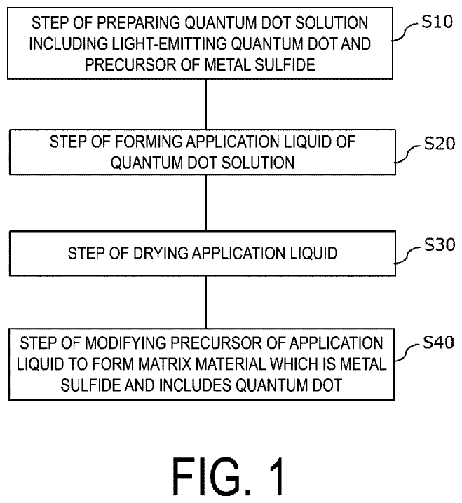

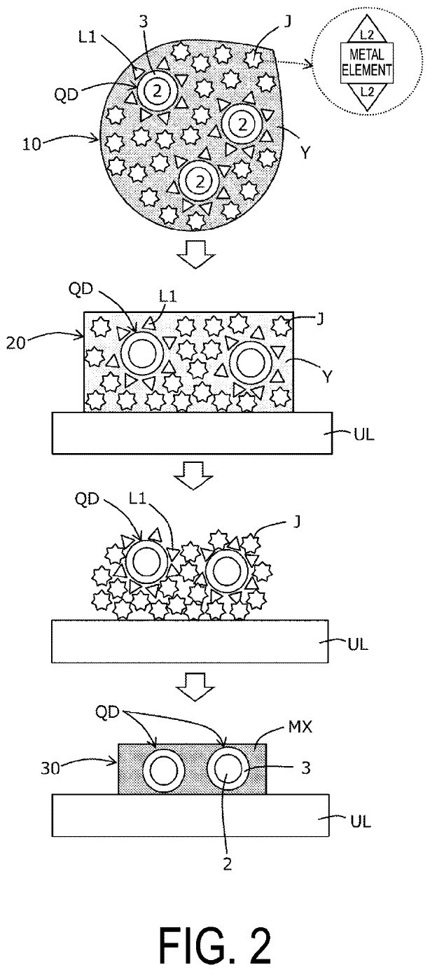

FIG. 1 is a flowchart depicting a method for forming a quantum dot layer according to an embodiment. FIG. 2 is a schematic view illustrating a method for forming a quantum dot layer according to the embodiment. As illustrated in FIG. 1 and FIG. 2, the method for forming a quantum dot layer according to the embodiment includes a step S10 of preparing a quantum dot solution 10 including a light-emitting quantum dot QD and a precursor J of a metal sulfide, a step S20 of forming an application liquid 20 of the quantum dot solution 10 on an underlayer UL, a step S30 of drying the application liquid 20, and a step S40 of modifying the precursor J of the application liquid 20 to form an inorganic matrix material MX, which is a metal sulfide A, including a plurality of quantum dots QD (filling spaces between the plurality of quantum dots QD). Thus, a quantum dot layer 30 including the plurality of quantum dots QD, and the inorganic matrix material MX configured to fill spaces between the plurality of quantum dots QD.

In the step S40, the precursor J can be decomposed and crystallized by performing at least one of heating and light irradiation on the application liquid 20. In the step S40, the application liquid 20 of the quantum dot solution 10 applied to the underlayer UL may be heated at 100 °C or more and 600 °C or less. In the step S40, the application liquid 20 of the quantum dot solution 10 applied to the underlayer UL including an organic layer may be heated at 100 °C or more and 250 °C or less.

In the step S40, the application liquid 20 of the quantum dot solution 10 applied to the underlayer UL may be irradiated with light having a wavelength from 200 nm to 400 nm. In the step S40, the application liquid 20 of the quantum dot solution 10 applied to the underlayer UL may be irradiated with laser light having a wavelength from 400 nm to 2000 nm.

The quantum dot solution 10 includes the light-emitting quantum dot QD, the precursor J of the metal sulfide A, and a solvent Y. The precursor J is a metal complex having a weight loss rate of 60% to 90% when heated from 50 °C to 200 °C. A solid obtained by heating the metal complex to 200 °C contains 80 wt % or more of an inorganic compound, and 50 wt % or more of the inorganic compound is the metal sulfide A. The weight loss rate is the ratio of the weight loss due to heating from 50 °C to 200 °C to the weight at 50 °C expressed as a percentage.

By using the precursor J having a weight loss rate of 60% to 90% when heated from 50 °C to 200 °C, it is possible to form the inorganic matrix material MX having a small amount of residues (for example, organic matter) in a low-temperature process as compared with the case of using a precursor having a weight loss rate of less than 60% when heated from 50 °C to 200 °C. Since the amount of the residues in the inorganic matrix material MX is small, when the quantum dot layer 30 is applied to a light-emitting element, the durability can be enhanced while maintaining the carrier injection property of the quantum dot layer 30. Thus, reduction in drive voltage and improvement in optical transparency are enabled. The low-temperature process makes it hard to cause the thermal damage to the carrier transport layer even when, for example, the underlayer UL is an organic carrier transport layer. The quantum dot layer 30 can be formed on a substrate having low thermal tolerance (for example, a flexible substrate).

The quantum dot solution 10 includes a ligand L1 of the quantum dot QD, and the ligand L1 of the quantum dot QD may have the same structure (relationship represented by the same structural formula) as a ligand L2 of the metal complex (precursor J). The ligand L1 increases the dispersibility of the quantum dot QD in the quantum dot solution 10. When the ligand L1 and the ligand L2 have the same structure, the modification (decomposition and crystallization) of the precursor J proceeds rapidly. In addition, preparation of the quantum dot solution 10 is facilitated. The ligand L1 may be coordinated to the quantum dot QD in an amount of 0.1 wt % or more.

The quantum dot QD has a core 2 and a shell 3, and the constituent material of the shell 3 may be the metal sulfide A. In this case, the ligand L1 is easily coordinated to the quantum dot QD, and the dispersibility of the quantum dot QD in the quantum dot solution 10 is increased.

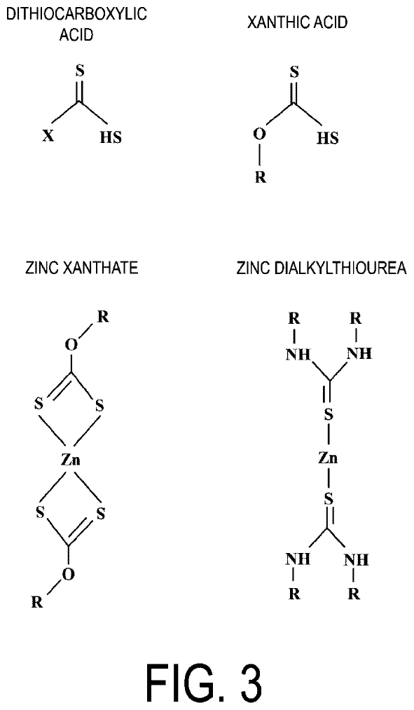

FIG. 3 is an example of structural formulae of ligands and metal complexes. The ligand L2 of the metal complex (precursor J) may be dithiocarboxylic acid.

Dithiocarboxylic acid has a structure represented by XC(═S)SH (X is a carbon substituent). The quantum dot QD may be modified with dithiocarboxylic acid. That is, the ligand L1 of the quantum dot QD may be the dithiocarboxylic acid. The metal complex (precursor J) may contain zinc element (Zn). The metal complex (precursor J) may be zinc dithiocarboxylate. The metal sulfide A may be zinc sulfide (ZnS). The ligand L2 of the metal complex (precursor J) may be xanthic acid. Xanthic acid has a structure represented by ROC(═S)SH (R is hydrogen, a hydrocarbon group, or the like). The metal complex (precursor J) may be zinc xanthate. The shell 3 of the quantum dot QD may be made of zinc sulfide (ZnS).

When the metal sulfide A is zinc sulfide, the precursor J is not limited to zinc xanthate. The precursor J may be zinc dialkylthiourea and the ligand L2 of the precursor J (metal complex) may be dialkylthiourea.

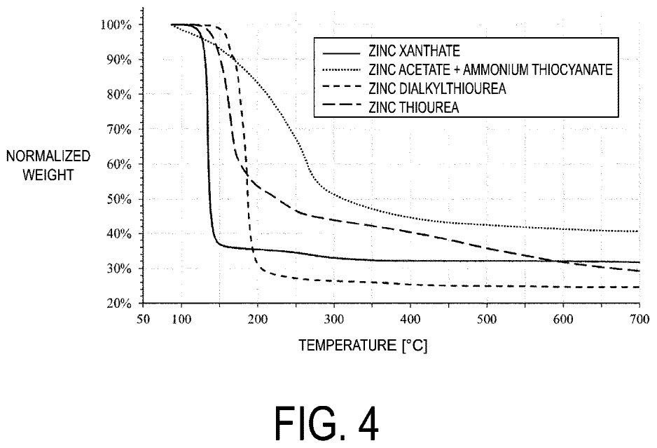

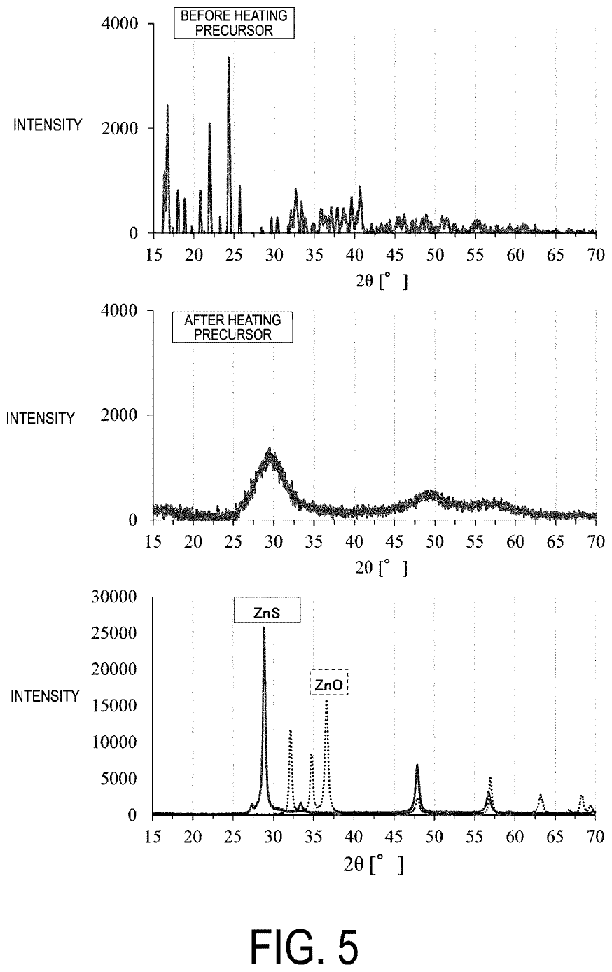

FIG. 4 is a graph depicting thermogravimetric characteristics of the metal complexes. The normalized weight on the vertical axis represents, based on the weight at 50 °C as a reference value (100%), the weight at 50 °C or higher as a percentage of the reference value. Here, a thermogravimetric analysis (TGA) apparatus was used to measure weight changes of four kinds of powders (zinc xanthate, a mixture of zinc acetate and ammonium thiocyanate, zinc alkylthiourea, and zinc thiourea) while heating them in nitrogen.

From FIG. 4, it can be seen that zinc xanthate (normalized weight at 200 °C: 35%, weight loss rate: 65%) and zinc dialkylthiourea (normalized weight at 200 °C: 30%, weight loss rate: 70%) are suitable as the precursor J of zinc sulfide having the weight loss rate of 60% to 90% when heated from 50 °C to 200 °C. In addition, it is found that a mixture of zinc acetate and ammonium thiocyanate (normalized weight at 200 °C: 85%, weight loss rate: 15%), in which the weight loss rate is less than 60% when heated from 50 °C to 200 °C, is not suitable as the precursor J.

For example, zinc xanthate can be prepared in the following manner. A mixed solution of an aqueous zinc chloride solution and an aqueous potassium xanthate solution (molar amount of zinc chloride: molar amount of potassium xanthate=1:2.2) is stirred for 24 hours, and a precipitate generated after the stirring is filtered. The precipitate obtained by filtration is washed three times with distilled water (removal of residual raw materials and by-product potassium chloride) and dried in nitrogen to obtain zinc xanthate (precursor J). Note that a solution in which zinc acetate and ammonium thiocyanate were dissolved in 2-methoxyethanol as a solvent (molar ratio of zinc acetate: molar ratio of ammonium thiocyanate=1:1) was stirred for 1 hour, and the solvent was removed to obtain a mixture of zinc acetate and ammonium thiocyanate.

In addition, the four powders (zinc xanthate, a mixture of zinc acetate and ammonium thiocyanate, zinc alkylthiourea, and zinc thiourea) were heated to 200 °C in nitrogen, and an obtained solid was subjected to the X-ray diffraction (XRD) measurement. For comparison, XRD of ZnO and ZnS powders were also measured.

FIG. 5 includes graphs depicting the X-ray diffraction profiles of zinc xanthate before and after heating and the X-ray diffraction profile of zinc sulfide. Since a peak specific to zinc sulfide appears in the graph after heating (in the case where zinc xanthate is heated to 150 °C), it is found that the precursor J denatured (decomposed, crystallized) into zinc sulfide.

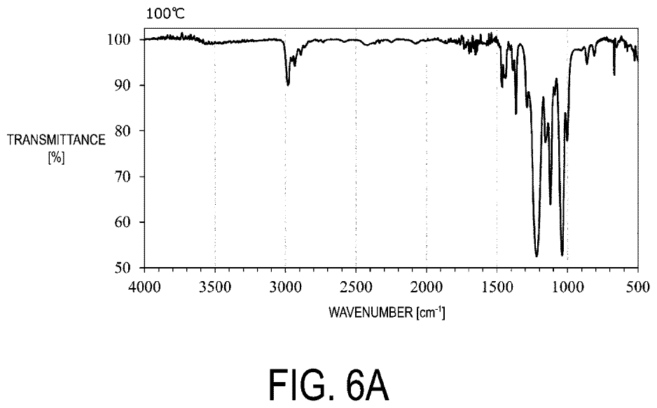

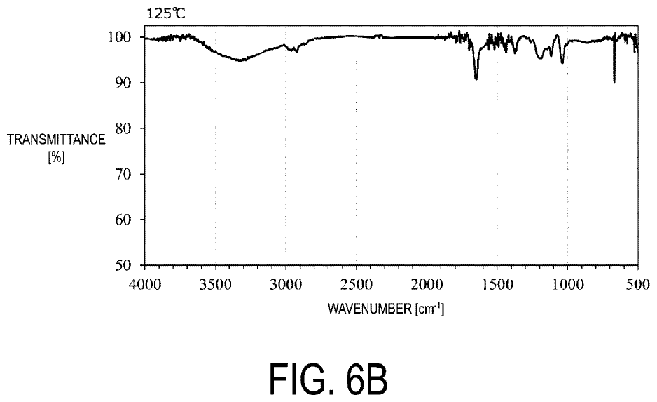

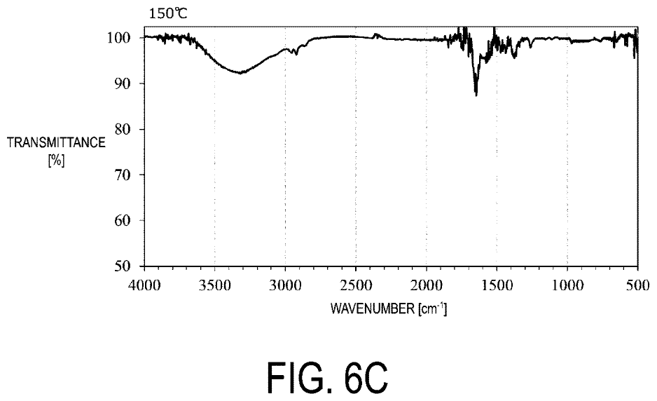

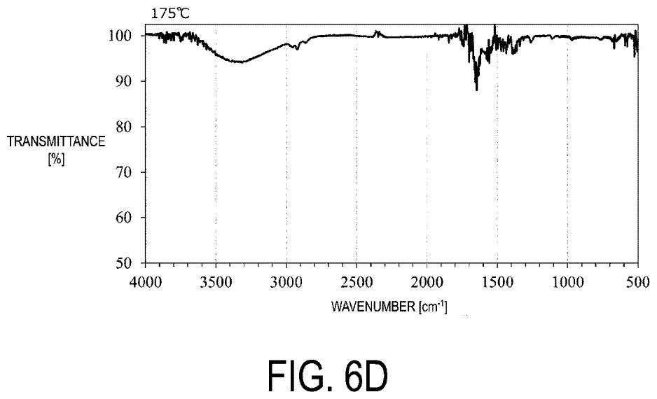

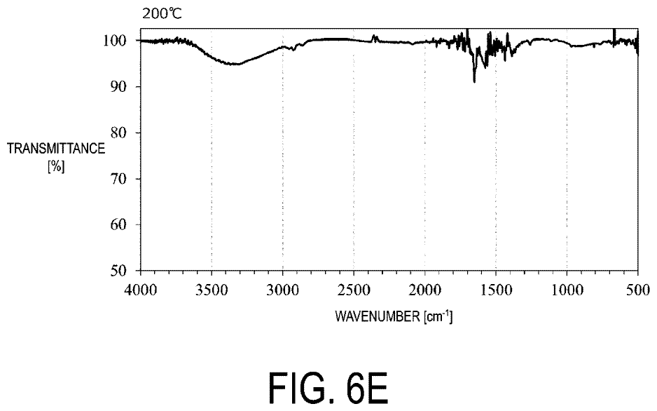

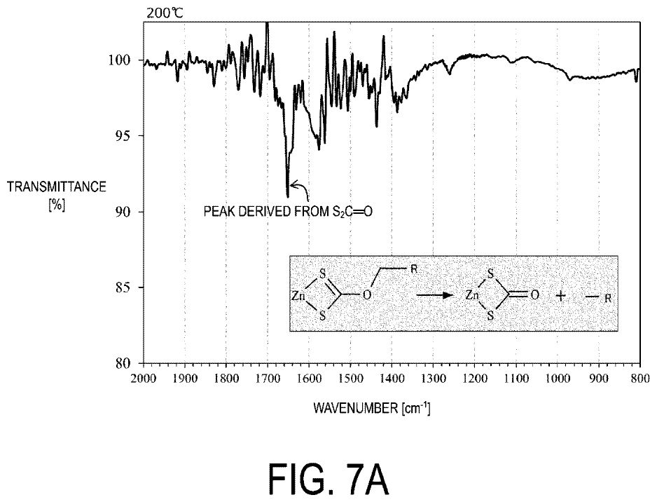

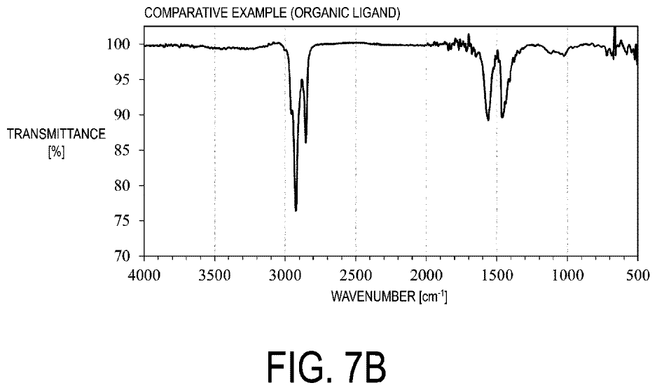

FIG. 6A to FIG. 6E are graphs depicting the results of Fourier transform infrared spectroscopy (FTIR) measurement after heating zinc xanthate. Note that the horizontal axis represents a wave number, the vertical axis represents a transmittance, the unit of the wave number is [cm⁻¹], and the unit of the transmittance is [%]. FIG. 6A depicts the measurement results after heating at 100 °C, FIG. 6B depicts the measurement results after heating at 125 °C, FIG. 6C depicts the measurement results after heating at 150 °C, FIG. 6D depicts the measurement results after heating at 175 °C, and FIG. 6E depicts the measurement results after heating at 200 °C. FIG. 7A is a graph depicting a part of FIG. 6E in an enlarged manner. FIG. 7B is a graph depicting the results of Fourier transform infrared spectroscopy (FTIR) measurements of an organic ligand.

It can be seen from FIG. 6A that the zinc xanthate as a metal complex has absorption peaks at 1040 cm⁻¹, 1122 cm⁻¹, and 1217 cm⁻¹ in the absorption spectrum of Fourier transform infrared spectroscopy. Therefore, it can be said that the quantum dot solution includes a ligand having absorption peaks at 1040 cm⁻¹, 1122 cm⁻¹, and 1217 cm⁻¹ in the absorption spectrum of Fourier transform infrared spectroscopy around the quantum dot QD.

The quantum dot solution contains a compound having absorption peaks at 1040 cm⁻¹, 1122 cm⁻¹, and 1217 cm⁻¹ in the absorption spectrum of Fourier transform infrared spectroscopy, the absorption peak intensity being less than 20% when heated to 200 °C

When zinc xanthate is heated to 125 °C or higher, a characteristic absorption spectrum appears that is not seen in the organic ligand depicted in FIG. 7B. That is, it is found that when zinc xanthate is heated, peaks near the wave numbers of 1000 to 1300 [cm⁻¹] and 3000 [cm⁻¹] disappear, but a peak appears at the wave number of 1650 [cm⁻¹]. As depicted in FIG. 7A, this peak is considered to be derived from a S₂C═O bond.

That is, the quantum dot layer (light-emitting layer) obtained by heating the application liquid of the quantum dot solution may include the plurality of light-emitting quantum dots QD, the metal sulfide (for example, an inorganic matrix material containing ZnS as a main component) including the plurality of quantum dots QD, and a compound having the S₂C═O bond. The quantum dot layer (light-emitting layer) may include a plurality of light-emitting quantum dots QD, a metal sulfide (for example, an inorganic matrix material containing ZnS as a main component) including the plurality of quantum dots QD, and a compound having a peak at 1650 cm⁻¹ in the absorption spectrum of Fourier transform infrared spectroscopy.

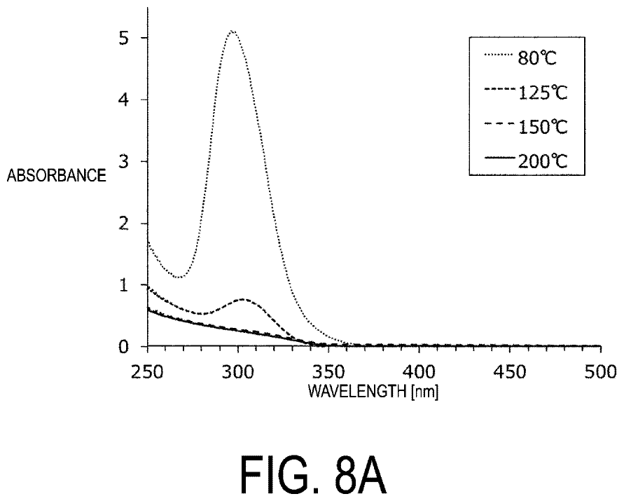

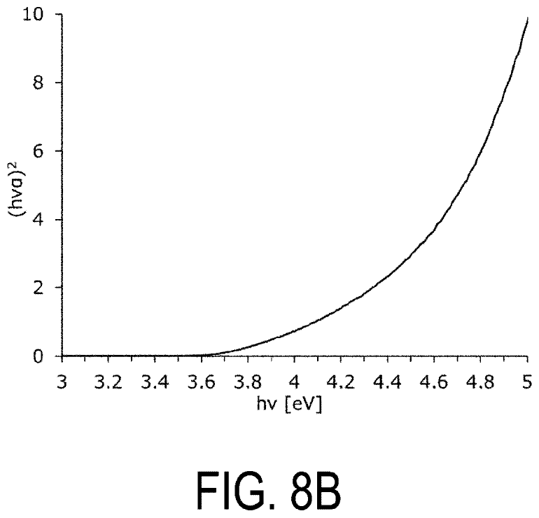

FIG. 8A is an ultraviolet-visible absorption spectrum (UV-VIS) of a thin film obtained by heating an application liquid of zinc xanthate. In particular, zinc xanthate was dissolved in DMF (N, N-dimethylformamide) to a concentration of 0.2 mol/l, and the solution was applied to glass at 2000 rpm and heated at each temperature for 30 minutes, and the ultraviolet-visible absorption spectrum of the thin film formed at each temperature was measured. It can be seen from FIG. 8A that the absorption peak of zinc xanthate at 305 nm disappeared and zinc xanthate was decomposed at 150 °C

FIG. 8B is a Tauc plot graph of a thin film obtained by heating an application liquid of zinc xanthate. The UV-VIS spectrum of the thin film obtained by heating the application liquid of zinc xanthate at 200 °C was illustrated by Tauc plot to calculate a band gap. In the graph, h is Planck's constant, v is the frequency of light, and a is the absorbance. The band gap of the obtained thin film was 3.65 eV. Since the generally known band gap of zinc sulfide is from^{3.6} eV to 3.7 eV, it is understood that Zinc sulfide having high transparency is formed.

The quantum dot QD used in the present embodiment may be fine particles having a particle diameter (outer diameter) of 1.0 [nm] to 100 [nm], and may be spherical or non-spherical in shape. The shape of the quantum dot QD is any shape as long as it falls within a range satisfying the above-mentioned particle diameter, and is not limited to a spherical three-dimensional shape (circular cross-sectional shape). The shape of the quantum dot QD may be, for example, a polygonal cross-sectional shape, a rod-shaped three-dimensional shape, a branch-shaped three-dimensional shape, or a three-dimensional shape having unevenness on the surface thereof, or a combination of them. The quantum dot QD may be composed of a semiconductor material and may be an inorganic semiconductor nanocrystal. The semiconductor material may have a constant band gap and may be a material in which electroluminescence occurs. The wavelength region of electroluminescence may be any one of a red region, a green region, and a blue region.

The quantum dot QD may have at least one of a crystal of a group II-VI semiconductor such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, or HgTe; a crystal of a group III-V semiconductor such as GaAs, GaP, InN, InAs, InP, or InSb; and a crystal of a group IV semiconductor such as Si or Ge.

The quantum dot layer including the inorganic matrix material MX can be used as a light-emitting layer of a light-emitting element. The inorganic matrix material MX containing an inorganic material (inorganic substance) as a main component may be a constituent element of the light-emitting layer including the plurality of quantum dots QD. The inorganic matrix material MX may be a member that is composed of an inorganic substance (for example, inorganic semiconductor) and that includes and holds other objects, and can be referred to as a base material, a matrix, or a filler. The inorganic matrix material MX may be solid at room temperature. The inorganic matrix material MX may include the plurality of quantum dots QD. The inorganic matrix material MX may be configured to fill a region (space) other than the plurality of quantum dots QD and fill spaces between the plurality of quantum dots QD, in the light-emitting layer (quantum dot layer). The inorganic matrix material MX may fill a region (void) other than the plurality of quantum dots QD in the light-emitting layer. The inorganic matrix material MX may be partially or completely filled in spaces between the plurality of quantum dots QD. The plurality of quantum dots QD may be embedded in the inorganic matrix material MX at intervals. The inorganic matrix material MX may be indicated as a portion in the light-emitting layer excluding the plurality of quantum dots QD. The inorganic matrix material MX may be configured to completely or incompletely fill a region (space) other than a quantum dot group in the light-emitting layer. Here, three or more quantum dots QD are collectively referred to as a quantum dot group. In the structure of the inorganic matrix material MX, the above-described structure need not be observed over the entire light-emitting layer as long as the structure described above is observed in the cross-section observation of the light-emitting layer in the width of about 100 nm. The inorganic matrix material MX in the quantum dot layer may be formed as a continuous film having an area equal to or larger than 1000 nm² in a plane direction orthogonal to the layer thickness direction. The continuous film means a film not partitioned by a material other than a material constituting the continuous film in one plane. The continuous film may be in the form of an integrated film connected without interruption by chemical bonding of the inorganic matrix material MX.

An outer periphery of the light-emitting layer is formed of the inorganic matrix material MX, and the quantum dots QD may be formed to be located away from the outer edge. The outer edge of the light-emitting layer need not be formed of only the inorganic matrix material MX, and the quantum dots QD may be partially exposed from the inorganic matrix material MX.

The inorganic matrix material MX may be the same material as the shell included in each of the plurality of quantum dots QD. It is desirable that the inorganic matrix material MX have a wider band gap than the core of the quantum dot QD. When the shell of the quantum dot QD and the inorganic matrix material MX cannot be distinguished from each other, the shell may be regarded as a part of the inorganic matrix material MX. The inorganic matrix material MX may contain a substance different from the main material (for example, ZnS) as an additive, impurity, or residue. When the light-emitting layer containing the inorganic matrix material MX is analyzed, the contained carbon atoms may be 5 atom % or less.

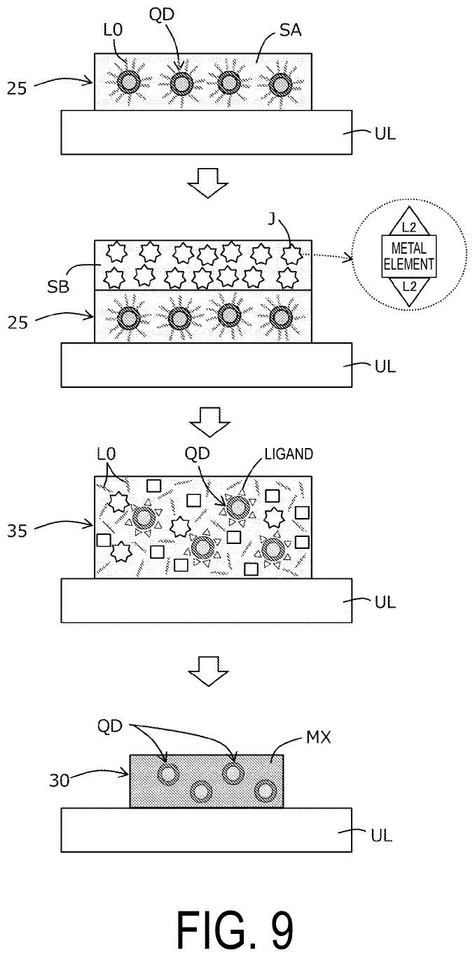

FIG. 9 is a schematic view illustrating another formation method of the quantum dot layer. In the formation method illustrated in FIG. 9, after the step of forming a coating film 25 including the organic ligand, the quantum dot QD, and a first solvent SA (non-polar solvent) and the step of applying a second solution including a metal xanthate (precursor J) and a second solvent SB (polar solvent) onto the coating film 25, a thin film 35 composed of the coating film 25 and the second solution is subjected to at least one treatment of heating and light irradiation to form the inorganic matrix material MX of the metal sulfide (for example, ZnS) including the plurality of quantum dots QD (filling spaces between the plurality of quantum dots QD). Thus, the quantum dot layer 30 including the plurality of quantum dots QD, and the inorganic matrix material MX configured to fill spaces between the plurality of quantum dots QD is formed. In the thin film 35, the ligand of the quantum dot QD is exchanged from an organic ligand L0 to xanthic acid (ligand L2 of metal xanthate). At this time, most of the separated organic ligands L0 are removed by dropping predetermined organic solvents onto the thin film 35 or the quantum dot layer before or after the treatment (including at least one of heating and light irradiation) on the thin film 35 and washing away (rinsing) the organic ligands L0.

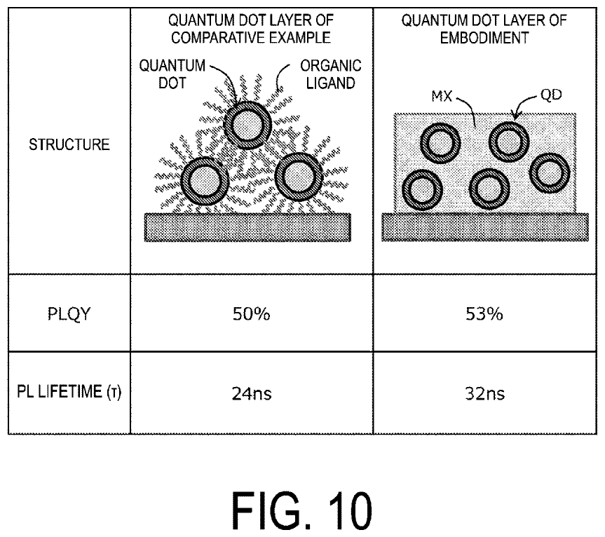

FIG. 10 is a table showing the results obtained by comparing the quantum dot layer of the comparative example and the quantum dot layer of the embodiment in terms of structure, PLQY (photoluminescence quantum efficiency), and PL lifetime (photoluminescence lifetime). The quantum dot layer of the embodiment is obtained by applying a solution including the quantum dot QD modified with xanthic acid and zinc xanthate (precursor J) to glass and heating the glass at 185 °C. It can be seen from FIG. 10 that the quantum dot layer (PLQY: 53%, PL lifetime: 32 [ns]) of the embodiment in which the inorganic matrix material MX includes the quantum dot QD is superior to the quantum dot layer (PLQY: 50%, PL lifetime: 24 [ns]) of the comparative example in which an organic ligand is disposed around the quantum dot in terms of PLQY and PL lifetime.

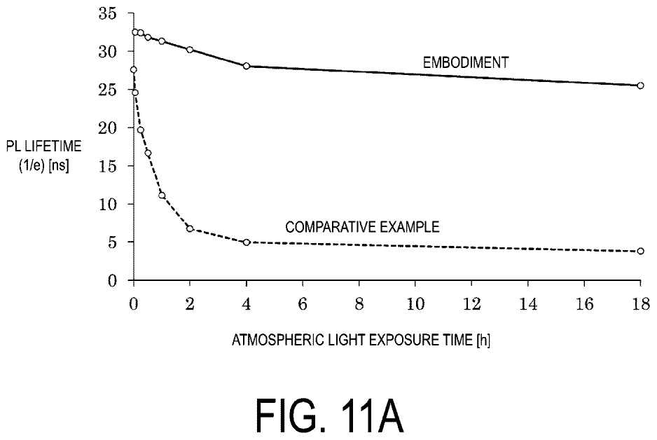

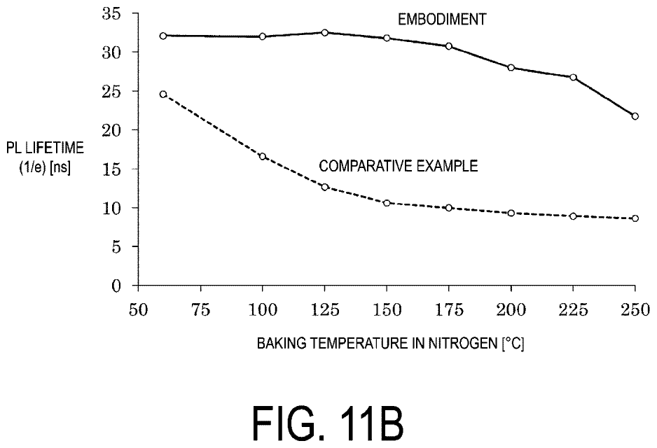

FIG. 11A is a graph depicting the results of the light exposure test in the atmosphere of the quantum dot layer of the comparative example and the results of the light exposure test in the atmosphere of the quantum dot layer of the embodiment. The quantum dot layer of the comparative example has a configuration in which an organic ligand is disposed around the quantum dot. The light is yellow light. From FIG. 11A, it can be seen that the quantum dot layer of the embodiment forming the inorganic matrix material (ZnS) is less likely to decrease in the PL lifetime after light exposure in the atmosphere (resistance to air exposure is improved) than that of the comparative example.

FIG. 11B is a graph depicting the results of the heating test in nitrogen of the quantum dot layer of the comparative example and the results of the heating test in nitrogen of the quantum dot layer of the embodiment. The quantum dot layer of the comparative example has a configuration in which an organic ligand is disposed around the quantum dot. From FIG. 11B, it can be seen that the PL lifetime after heating is less likely to decrease (heat resistance is improved) in the quantum dot layer of the embodiment than in the comparative example.

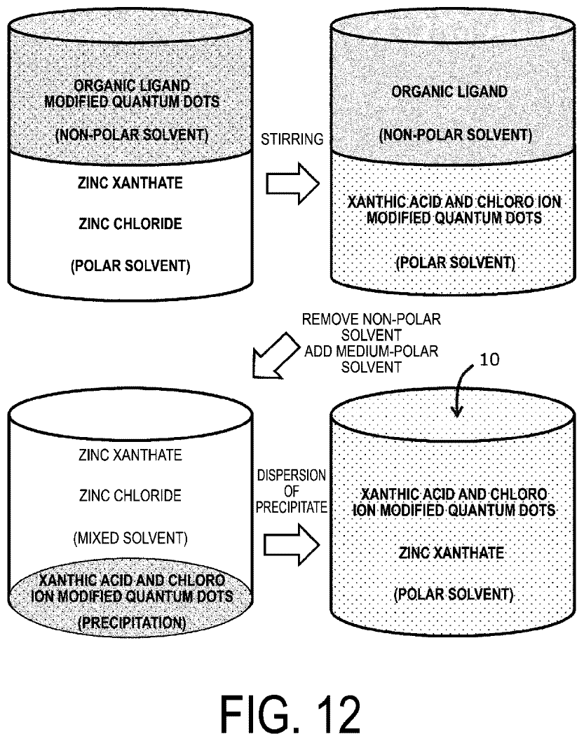

FIG. 12 is a schematic view illustrating an example of the preparation method of the quantum dot solution. A solution (1 mg/mL) obtained by dispersing the red light-emitting quantum dot (core: InP, shell: ZnS) modified with a non-polar organic ligand in a non-polar solvent (first solvent: for example, hexane), a solution (0.1 mol/L) obtained by dissolving zinc ethylxanthate (xanthic acid source) in a polar solvent (second solvent: for example, NMF: N-methylformamide), and a solution (0.2 mol/L) obtained by dissolving zinc chloride (halogen source) in a polar solvent (second solvent) were mixed and stirred vigorously for 24 hours in a state where the upper hexane layer and the lower NMF layer were separated from each other. Here, the halogen source is, for example, a halogen compound, and the halogen compound may be a metal halide or an ammonium halide. The xanthogenic acid source and the halogen source may contain the same metal element. As a result, the quantum dot QD moved to the lower layer and was modified with ethyl xanthic acid and a chloro ion (halogen). Thereafter, the upper hexane layer was removed, and a medium-polar solvent (third solvent: for example, ethyl acetate) was added to the lower layer to precipitate the lower layer. At this time, zinc chloride and zinc ethylxanthate are not precipitated, so that the quantum dots modified with xanthic acid and chloro ions are precipitated. By dispersing a predetermined amount of the precipitate (including quantum dots modified with xanthic acid and chloro ion) and a predetermined amount of zinc ethylxanthate (ZnS precursor) in a polar solvent (fourth solvent: for example, DMF), the concentrations of the quantum dots and zinc ethylxanthate can be adjusted to desired concentrations.

The xanthic acid may have an alkyl chain having 1 to 5 carbon atoms. The xanthic acid may have an ether chain having 1 to 20 carbon atoms. In these cases, the solvent may be a polar solvent including at least one of a formamide solvent, an acetamide solvent, an ester solvent, a ketone solvent, a sulfoxide solvent, an ether solvent, a thioether solvent, and a nitrile solvent. The xanthic acid may have an alkyl chain with 6 or more carbon atoms, in which case the solvent may be a non-polar solvent.

The xanthic acid source used to prepare the quantum dot solution may be a metal xanthate, such as zinc ethylxanthate or potassium ethylxanthate.

As illustrated in FIG. 12, the quantum dot solution may include halogen, and the quantum dot QD may be modified with dithiocarboxylic acid (for example, xanthic acid) and halogen.

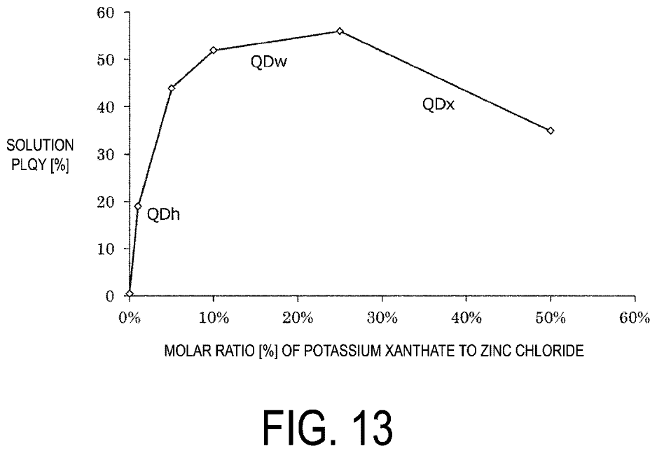

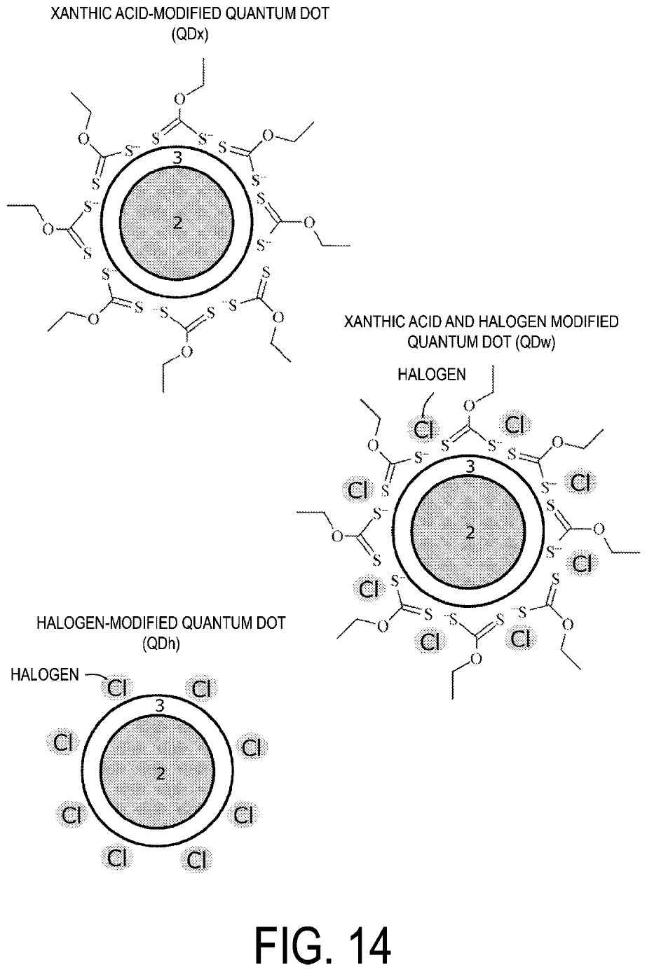

FIG. 13 is a graph depicting the relationship between the molar ratio of potassium xanthate to zinc chloride (chloro ion source) in a solution used for preparation of a quantum dot solution and PLQY. FIG. 14 includes schematic views illustrating a modification state of the quantum dots. It was found from FIG. 13 that, as the molar ratio of potassium xanthate increased from 0% to 50%, a xanthic acid-modified quantum dot QDx changed to a xanthic acid- and halogen-modified quantum dot QDw and then to a halogen-modified quantum dot QDh, and that PLQY of the xanthic acid- and halogen-modified quantum dot QDw was higher (than that of QDx and QDh).

In addition, it was found that the xanthic acid is coordinated to the surface of the quantum dot QD to increase the PL intensity. It has also been found that xanthic acid is substantially decomposed by heating and does not adversely affect photoluminescence or electroluminescence. It was also found that the dispersibility of the quantum dot QD in a polar solvent is enhanced by coordinating halogen (chloro ion) with xanthic acid (QDw in FIG. 14).

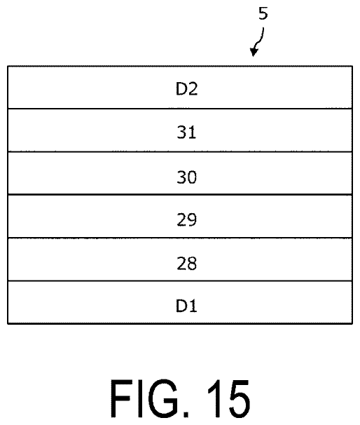

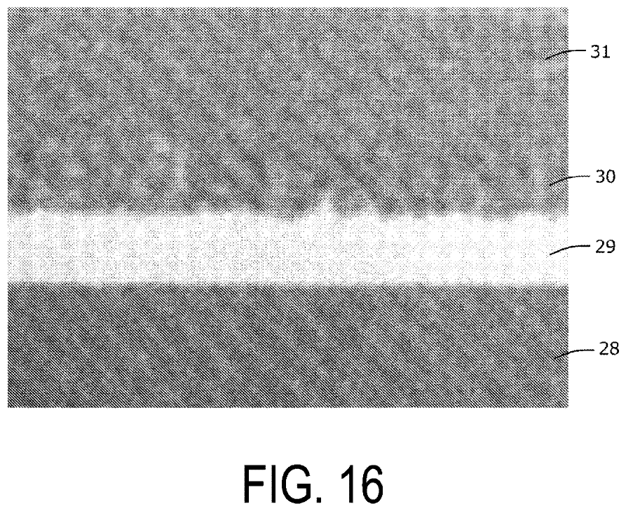

FIG. 15 is a schematic cross-sectional view illustrating a configuration example of a light-emitting element of the present embodiment. FIG. 16 is a cross-sectional photograph illustrating a configuration example of a light-emitting element of the present embodiment. As illustrated in FIG. 15 and FIG. 16, a light-emitting element 5 includes a first electrode D1 (anode), a hole injection layer 28, a hole transport layer 29, the light-emitting layer 30, an electron transport layer 31, and a second electrode D2 (cathode) in this order.

The light-emitting element 5 can be formed, for example, as below. That is, it performs steps of: preparing a quantum dot solution including 15 mg/ml of a quantum dot QD modified with ethylxanthic acid and halogen (chloro ion) (DMF solution including 15 mg/ml of a quantum dot modified with a chloro ion and xanthic acid and 0.04 mol/l (12 mg/ml) of Zinc xanthate) using 0.04 mol/l (12 mg/ml) of a solution obtained by dissolving Zinc ethylxanthate in DMF solvent; forming a first electrode D1 using an ITO (indium tin oxide); applying and forming the hole injection layer 28 on the first electrode D1 using NiO nanoparticles (step of applying 15 mg/ml of NiO nanoparticles at 2000 rpm on the ITO as anode in nitrogen may be included); applying and forming the hole transport layer 29 using P-TPD, for example, onto the hole injection layer 28 (step of applying P-TPD dissolved in chlorobenzene at the concentration of 8 mg/ml at 1500 rpm may be included); applying the quantum dot solution prepared by the above steps on the hole transport layer 29 by spin coating (for example, at a rotational speed of 2000 rpm) and then heating the application liquid at 150 °C for 30 minutes to form the light-emitting layer 30 (quantum dot layer); applying and forming the electron transport layer 31 using ZnMgO (step of applying ZnMgO nanoparticles may be included); and forming the second electrode D2 using Ag (Ag vapor deposition step may be included). Note that it is preferable that the quantum dot solution include the quantum dot QD at a concentration of 5 to 100 mg/ml and the metal complex (for example, zinc ethylxanthate) at a concentration of 1 to 100 mg/ml. Note that as a comparative example, a light-emitting element including a light-emitting layer obtained by heating an application liquid of an octane solution including 15 mg/ml of the quantum dot modified with an organic ligand at 90 °C was fabricated. In the embodiment and the comparative example, the light-emitting elements other than the light-emitting layer were common, and commercially available InP/ZnS emitting red light was used for the quantum dot.

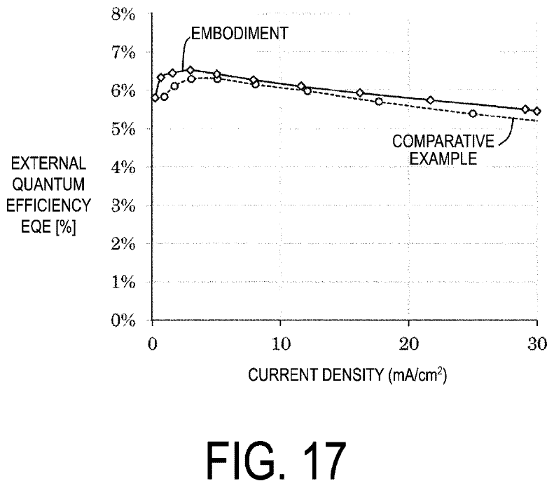

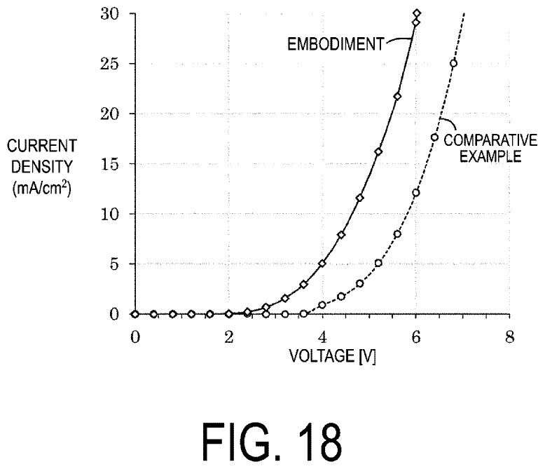

FIG. 17 is a graph depicting current density-external quantum-effect characteristics of the light-emitting element. It can be seen that the maximum value of the external quantum efficiency (EQE) is 6.5% in the embodiment and 6.4% in the comparative example. FIG. 18 is a graph depicting voltage (applied voltage)-current density characteristics of the light-emitting element. It can be seen that the current density at the time of 6 V application is 29 mA/m² in the embodiment and 12 mA/m² in the comparative example. According to the embodiment, since carrier injection into the light-emitting layer is facilitated, it is possible to reduce a voltage necessary for a desired light emission luminance (current density).

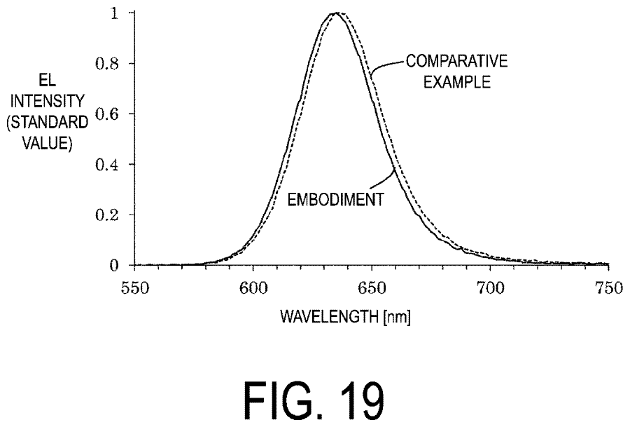

FIG. 19 is a graph depicting EL spectra at a current density of 10 mA/m² in the embodiment and the comparative example. In the embodiment, since the sulfide medium suppresses the Förster energy transfer between the quantum dots, the peak wavelength is shifted to the shorter wavelength side than that of the comparative example, and the emission peak is the same as that in the solution.

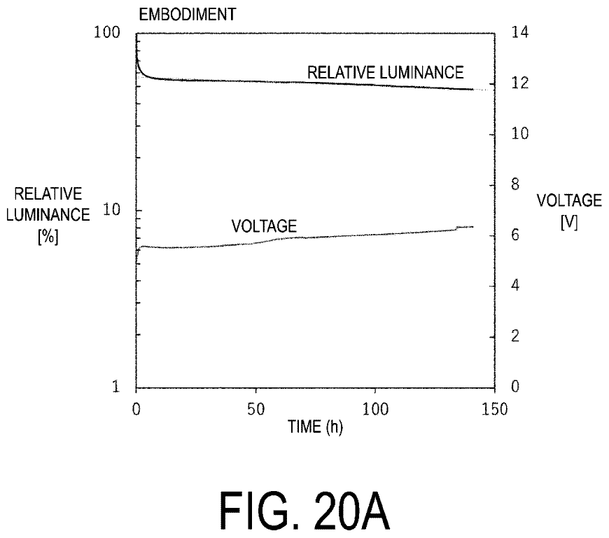

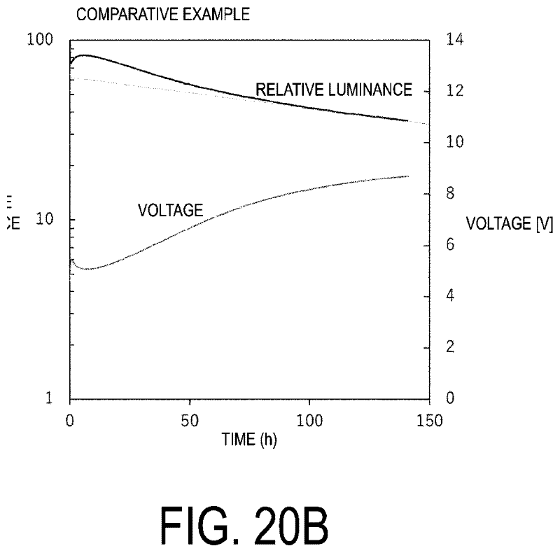

FIG. 20A is a graph depicting temporal changes in relative luminance and voltage when a constant current of 25 mA/m² is continuously supplied to the light-emitting element of the embodiment. FIG. 20B is a graph depicting temporal changes in relative luminance and voltage when a constant current of 25 mA/m² is continuously supplied to the light-emitting element of the comparative example. When the luminance half-life time is calculated by linearly approximating the luminance attenuation curve, the luminance half-life time of the comparative example is 52 hours. The luminance half-life time of the embodiment was 620 hours, which was a significant improvement with respect to the comparative example. Further, the voltage rise in the embodiment was much more gradual than that in the comparative example.

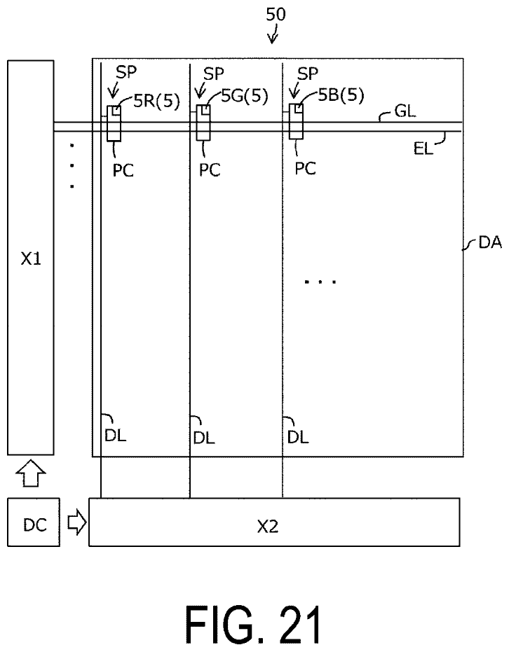

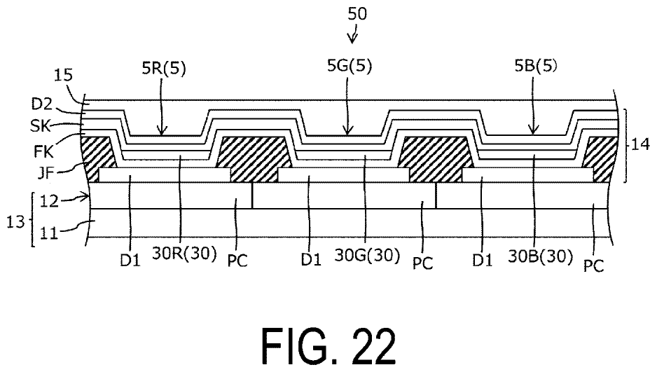

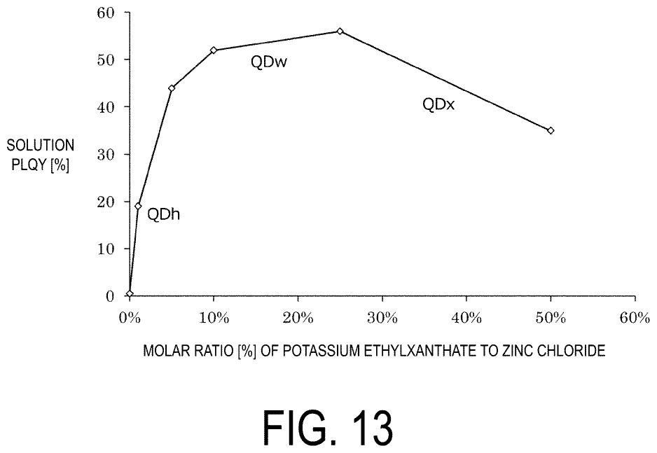

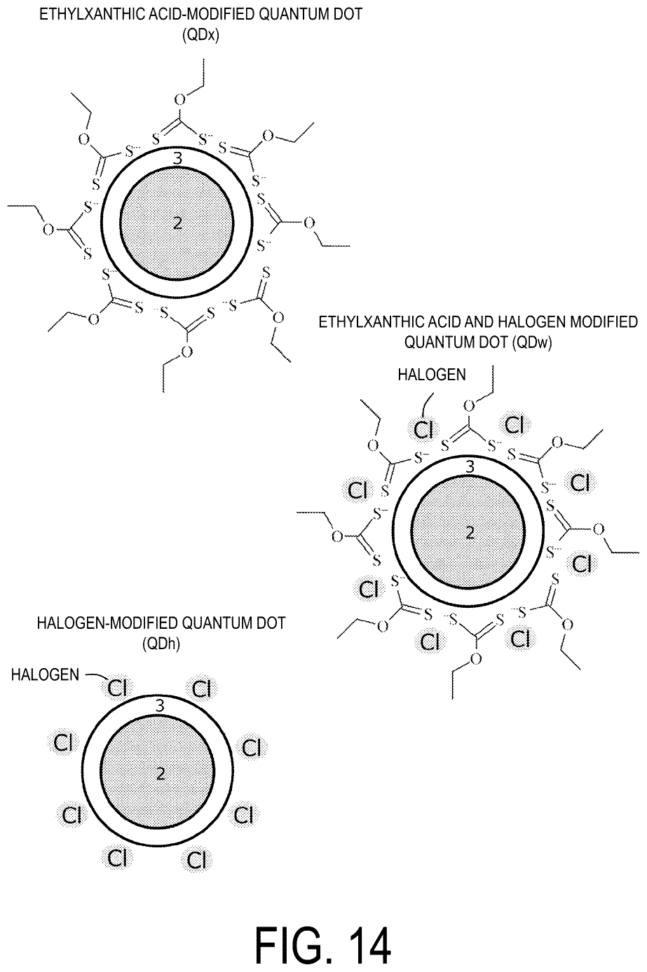

FIG. 21 is a schematic diagram illustrating a configuration example of a display device according to the embodiment. FIG. 22 is a cross-sectional view illustrating a configuration example of a display device according to the embodiment. As illustrated in FIG. 21, a display device 50 includes a display portion DA including a plurality of subpixels SP, a first driver X1 and a second driver X2 that drive the plurality of subpixels SP, and a display control unit DC that controls the first driver X1 and the second driver X2. The subpixel SP includes the light-emitting element 5 and a pixel circuit PC connected to the light-emitting element 5. The pixel circuit PC may be connected to a scanning signal line GL, a data signal line DL, and a light emission control line EL. The scanning signal line GL and the light emission control line EL may be connected to the first driver X1, and the data signal line DL may be connected to the second driver X2.

The display device 50 may include a pixel circuit substrate 13 including a substrate 11 and a pixel circuit layer 12, a light-emitting element layer 14, and a sealing layer 15. A glass substrate or a resin substrate can be used for the substrate 11. The substrate 11 may have flexibility. The pixel circuit layer 12 includes, for example, a plurality of pixel circuits PC arranged in an inorganic matrix. The pixel circuit PC includes: a pixel capacity in which a gray scale signal is written, a transistor that controls a current value of the light-emitting element 5 in accordance with the gray scale signal, a transistor connected to the scanning signal line GL and the data signal line DL, and a transistor connected to the light emission control line EL.

As illustrated in FIG. 22, the display device 50 includes the pixel circuit substrate 13 and the light-emitting element layer 14. The light-emitting element layer 14 may include, in order from the pixel circuit substrate 13 side, the first electrode D1, an edge cover film JF covering an edge of the first electrode D1, a first function layer FK, the light-emitting layer (quantum dot layer) 30, a second function layer SK, and the second electrode D2. The first function layer FK may have a hole injection function and a hole transport function, and the second function layer SK may have an electron transport function. The light-emitting element layer 14 may include a light-emitting element 5R including a light-emitting layer 30R emitting red light, a light-emitting element 5G including a light-emitting layer 30G emitting green light, and a light-emitting element 5B including a light-emitting layer 30B emitting blue light. The sealing layer 15 includes an inorganic insulating film such as a silicon nitride film or a silicon oxide film, and prevents foreign matter (water, oxygen, or the like) from entering the light-emitting element layer 14.

As the material of the first function layer FK, an organic material such as poly[(9,9-dioctylfluoreny1-2,7-diyl)-co-(4,4′-(N-4-sec-butylphenyl))diphenylamine)] (TFB), poly(4-butyltriphenylamine) (p-TPD), poly(9-vinylcarbazole) (PVK), [9,9′-[1,2-phenylenebis(methylene)]bis[N3, N3, N6, N6-tetrakis(4-methoxyphenyl)-9H-carbazole-3,6-diamine] (V886), or 7,7′-bi[1,4]benzoxazino[2,3,4-kl]phenoxazine (HN-D1), or an inorganic material such as NiO nanoparticles can be used.

As the material of the second function layer SK, an organic material such as (2,2′,2″-(1,3,5-benzintriyl)-tris(1-phenyl-1-H-benzimidazole) (TPBi), bathocuproine (BCP), or nanoparticles of an organometallic complex, or an inorganic material such as nanoparticles of an n-type oxide semiconductor can be used. Examples of the organometallic complex include a tris(8-quinolinol)aluminum complex (Alq3). Examples of the n-type oxide semiconductor include metal oxides such as ZnO and ZnMgO.

The quantum dot layer 30 illustrated in FIG. 2 and the like is used as the light-emitting layer in FIG. 22, but it is not limited thereto. The quantum dot layer 30 illustrated in FIG. 2 or the like can also be used as a wavelength conversion layer or an optical sensor layer. It is also possible to form a power generating element including the quantum dot layer 30 between a pair of electrodes. For example, an electromotive force may be generated by generating holes and electrons in the quantum dot QD from light incident on the quantum dot layer 30 and transporting the holes and the electrons to the electrodes.

The embodiments described above are for the purpose of illustration and description and are not intended to be limiting. It will be apparent to those skilled in the art that many variations will be possible in accordance with these examples and descriptions.

1. A quantum dot solution comprising:
a light-emitting quantum dot;
a precursor of a metal sulfide; and
a solvent,
wherein the precursor is a metal complex having a weight loss rate of 60% to 90% in a case of being heated from 50°C to 200°C,
a solid obtained after the metal complex is heated to 200°C includes 80 wt % or more of an inorganic compound, and
50 wt % or more of the inorganic compound is the metal sulfide.

2. The quantum dot solution according to claim 1,
wherein the quantum and the metal complex each have a ligand with an identical structure.

3. The quantum dot solution according to claim 2,
wherein the ligand of the quantum dot is coordinated to the quantum dot in an amount of 0.1 wt % or more.

4. The quantum dot solution according to claim 1,
wherein the metal complex includes a ligand, and
the ligand is a dithiocarboxylic acid or dialkylthiourea.

5. (canceled)

6. The quantum dot solution according to claim 4, wherein the ligand of the metal complex is dithiocarboxylic acid, and the dithiocarboxylic acid is xanthic acid.

7. The quantum dot solution according to any one of claims 1,
wherein the metal complex includes a zinc element.

8. The quantum dot solution according to claims 1, further comprising:
halogen.

9. The quantum dot solution according to claim 4,
wherein the quantum dot is modified with dithiocarboxylic acid.

10. The quantum dot solution according to claim 4,
wherein the quantum dot is modified with dithiocarboxylic acid and halogen.

11. The quantum dot solution according to claim 6,
Wherein the xanthic acid has an alkyl chain having 1 to 5 carbon atoms or an alkyl chain having 6 or more carbon atoms.

12. The quantum dot solution according to claim 6,
wherein the xanthic acid has an ether chain having 1 to 20 carbon atoms.

13. The quantum dot solution according to claim 11,
wherein the solvent is a polar solvent including at least one of a formamide solvent, an acetamide solvent, an ester solvent, a ketone solvent, a sulfoxide solvent, an ether solvent, a thioether solvent, and a nitrile solvent.

14. (canceled)

15. The quantum dot solution according to claim 6,
wherein the xanthic acid has an alkyl chain having 6 or more carbon atoms, and
the solvent is a non-polar solvent.

16. The quantum dot solution according to claims 1,
wherein the quantum dot includes a shell composed of the metal sulfide.

17. The quantum dot solution according to claims 1,
wherein a ligand is around the quantum dot, and
the ligand or the metal complex has absorption peaks at 1040 cm⁻¹, 1122 cm⁻¹, and 1217 cm⁻¹ in an absorption spectrum of Fourier transform infrared spectroscopy.

18. (canceled)

19. The quantum dot solution according to claims 1, further comprising:
a compound having absorption peaks at 1040 cm⁻¹, 1122 cm⁻¹, and 1217 cm⁻¹ in an absorption spectrum of Fourier transform infrared spectroscopy, and an absorption peak intensity becomes less than 20% by heating to 200 °C

20. The quantum dot solution according to claims 1,
wherein the quantum dot solution includes the quantum dot at a concentration of 5 to mg/ml and the metal complex at a concentration of 1 to 100 mg/ml.

21-26. (canceled)

27. A light-emitting element comprising:
an anode and a cathode; and
a light-emitting layer located between the anode and the cathode,
wherein the light-emitting layer includes a plurality of light-emitting quantum dots, metal sulfide including the plurality of quantum dots, and a compound having a S₂C═O bond.

28. A light-emitting element comprising:
an anode and a cathode; and
a light-emitting layer located between the anode and the cathode,
wherein the light-emitting layer includes a plurality of light-emitting quantum dots, a metal sulfide including the plurality of quantum dots, and a compound having a peak at 1650 cm⁻¹ in an absorption spectrum of Fourier transform infrared spectroscopy.

29. The light-emitting element according to claim 27,
wherein the metal sulfide is zinc sulfide.

30-36. (canceled)
